(19) United States
(12) Patent Application Publication
(10) Pub. No.: US 2026/0141840 A1
(43) Pub. Date: May 21, 2026

(54) Electronic Device with a Display and a System-in-Package

(71) Applicant: Apple Inc., Cupertino, CA (US)

(72) Inventors: Anshi Liang, Saratoga, CA (US); Cheng-Chih Hsieh, Santa Clara, CA (US); Flynn P. Carson, Redwood City, CA (US); Han-Chieh Chang, San Jose, CA (US); Job Nalianya, San Jose, CA (US); Jonas Hsu, Salt Lake City, UT (US); Joshua G. Wurzel, East Palo Alto, CA (US); Junnan Zhao, San Jose, CA (US); Ka Kuen Wan, San Jose, CA (US); Kasra M. Omid-Zohoor, Sunnyvale, CA (US); Ken Hsuan Liao, Los Gatos, CA (US); Kumar Nagarajan, Cupertino, CA (US); Lingqi Wu, Fremont, CA (US); Marc J. DeVincentis, Palo Alto, CA (US); Martin R. Kardasz, Mountain View, CA (US); Paolo Sacchetto, Cupertino, CA (US); Pierpaolo Lupo, Cupertino, CA (US); Po-Jui Chen, Cupertino, CA (US); Ryan Mesch, Phoenix, AZ (US); Shin-Hung Yeh, Taipei (TW); Shreyas Tater, Santa Clara, CA (US); Sinan Alousi, Campbell, CA (US); Snehal T. Jariwala, San Jose, CA (US); Tsung-Ting Tsai, San Jose, CA (US); Victor H. Yin, Cupertino, CA (US); Wei H. Yao, Saratoga, CA (US); Ying-Chih Wang, Sunnyvale, CA (US); Yong Wang, San Jose, CA (US)

(21) Appl. No.: 19/359,278

(22) Filed: Oct. 15, 2025

Related U.S. Application Data
(60) Provisional application No. 63/723,510, filed on Nov. 21, 2024.

(51) Int. Cl. G09G 3/20; H05K 3/28

(52) U.S. Cl. CPC G09G 3/2096; H05K 3/284; G09G 2300/0408

(57) ABSTRACT

An electronic device may have a display. The display may include an array of pixels formed on a display panel. A system-in-package (SiP) may include a substrate, electronic components mounted on the substrate, and mold material that overlaps and conforms to the electronic components. A portion of the substrate that is not overlapped by the mold material may be bonded to the display panel. The electronic components mounted on the substrate of the SiP may include a timing controller integrated circuit and/or a display driver integrated circuit. A plurality of display driver integrated circuit chiplets may be mounted on the substrate of the SiP. The substrate of the SiP may be electrically connected to the display panel by side-wrapped conductive traces. The substrate of the SiP may have portions with different thicknesses.

This application claims the benefit of U.S. provisional patent application No. 63/723,510, filed Nov. 21, 2024, which is hereby incorporated by reference herein in its entirety.

### BACKGROUND

This relates generally to electronic devices, and, more particularly, to electronic devices with displays.

Electronic devices often include displays. For example, an electronic device may have an organic light-emitting diode (OLED) display based on organic light-emitting diode pixels or a liquid crystal display (LCD) based on liquid crystal display pixels. The display may include display driver circuitry that is configured to provide display data to the pixels and gate driver circuitry that is configured to control the pixels.

It is within this context that the embodiments herein arise.

### SUMMARY

An electronic device may include a display panel comprising an array of pixels and a first plurality of conductive contacts and a system-in-package comprising a substrate, a second plurality of conductive contacts on the substrate, conductive traces within the substrate, electronic components mounted on the substrate, and mold material that overlaps and conforms to the electronic components. The second plurality of conductive contacts may be bonded to the first plurality of conductive contacts, the substrate may have a footprint, and the mold material may overlap less than 50% of the footprint.

An electronic device may include a display panel comprising first and second opposing surfaces connected by an edge surface, a system-in-package that overlaps the display panel in a direction parallel to the edge surface of the display panel, and conductive traces that extend in the direction parallel to the edge surface of the display panel. The system-in-package may include a substrate, electronic components mounted on the substrate, and mold material that overlaps and conforms to the electronic components, the conductive traces may electrically connect the display panel to the substrate, and the display panel may include an array of pixels at the first surface.

An electronic device may include a display panel comprising an array of pixels and a system-in-package comprising a substrate, electronic components mounted on the substrate, and mold material that overlaps and conforms to the electronic components. A portion of the substrate that is not overlapped by the mold material may be bonded to the display panel.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3A is a cross-sectional side view of an illustrative display with a system-in-package that has a substrate bonded to a display panel in accordance with some embodiments.

FIG. 3B is a top view of the illustrative display of FIG. 3A in accordance with some embodiments.

FIG. 4 is a cross-sectional side view of an illustrative display with a system-in-package that includes a display driver integrated circuit and that has a substrate bonded to a display panel in accordance with some embodiments.

FIG. 5 is a cross-sectional side view of an illustrative system-in-package that has a plurality of display driver integrated circuit chiplets bonded to a substrate in accordance with some embodiments.

FIG. 6 is a cross-sectional side view of an illustrative display with a system-in-package that has a substrate with multiple discrete portions with different thicknesses bonded to a display panel in accordance with some embodiments.

FIG. 7 is a cross-sectional side view of an illustrative display with side-wrapped conductive traces that conform to edge surfaces of a display panel and a system-in-package in accordance with some embodiments.

FIG. 8 is a cross-sectional side view of an illustrative display with side-wrapped conductive traces that conform to edge surfaces of a silicon structure between a display panel and a system-in-package in accordance with some embodiments.

FIG. 9 is a cross-sectional side view of an illustrative display with a system-in-package that has a substrate with a protruding portion that is bonded to a display panel in accordance with some embodiments.

### DETAILED DESCRIPTION

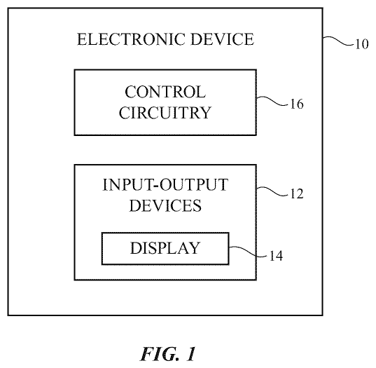

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

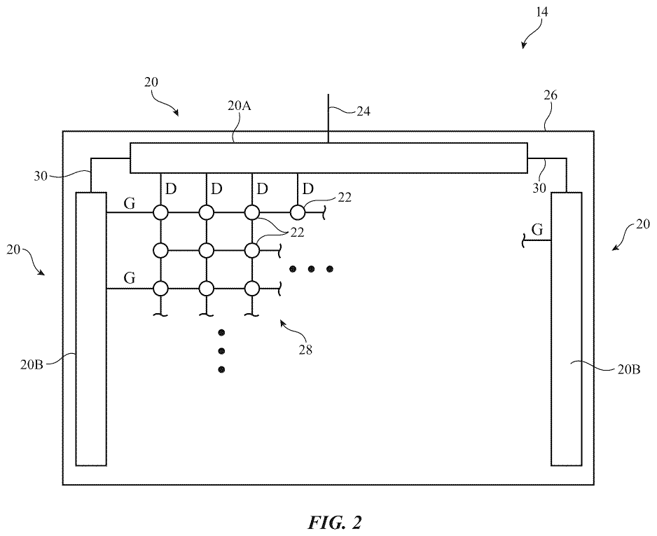

FIG. 2 is a diagram of an illustrative display 14. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, silicon layers, composite films that include polymer and inorganic materials, metallic foils, etc.

Display 14 may have an array of pixels 22 for displaying images for a user such as pixel array 28. Pixels 22 in array 28 may be arranged in rows and columns. The edges of array 28 may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels. Pixels of other colors such as cyan, magenta, and yellow might also be used.

Display driver circuitry 20 may be used to control the operation of pixels 28. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 as shown in FIG. 2.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D while issuing control signals to supporting display driver circuitry such as gate driver circuitry 20B over signal paths 30. With the illustrative arrangement of FIG. 2, data lines D run vertically through display 14 and are associated with respective columns of pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally across display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.).

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., thin-film circuitry on substrate 26) that responds to the control and data signals from display driver circuitry 20.

Gate driver circuitry 20B may include blocks of gate driver circuitry such as gate driver row blocks. Each gate driver row block may include circuitry such output buffers and other output driver circuitry, register circuits (e.g., registers that can be chained together to form a shift register), and signal lines, power lines, and other interconnects. Each gate driver row block may supply one or more gate signals to one or more respective gate lines in a corresponding row of the pixels of the array of pixels in the active area of display 14.

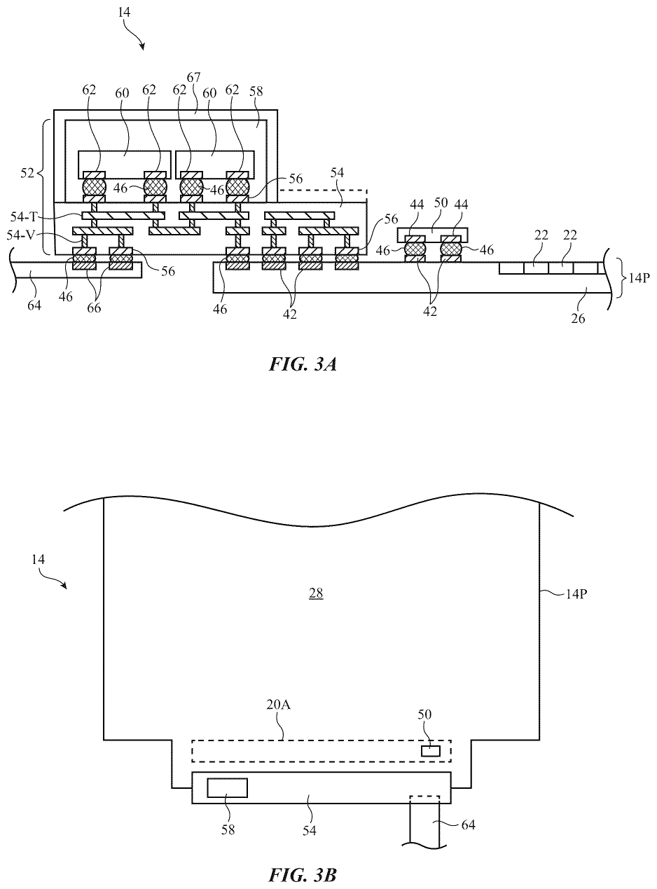

FIG. 3A is a cross-sectional side view of an illustrative display. As shown in FIG. 3A, display 14 includes a display panel 14P. The display panel 14P includes a substrate 26 with an array of pixels 22 (similar to as previously shown in FIG. 2). Display 14P has first and second opposing surfaces (e.g., upper and lower surfaces) with an edge surface that connects the first and second surfaces. The array of pixels is formed at the upper surface of the display panel. Display 14P additionally includes a plurality of contacts 42 on the upper surface that are used to provide and/or receive electrical signals from additional electronic components within electronic device 10. Contacts 42 (sometimes referred to as contact pads 42, conductive contacts 42, etc.) may be formed on the same surface of substrate 26 as pixels 22 (e.g., both pixels 22 and contacts 42 are on the upper surface of substrate 26 in FIG. 3A), the edge surface of substrate 26, and/or the opposite surface of substrate 26 as pixels 22 (e.g., contacts 42 may be positioned on the lower surface of substrate 26 in FIG. 3A).

In the example of FIG. 3A, a display driver integrated circuit (DDIC) 50 is included in the electronic device. The display driver integrated circuit 50 includes display driver circuitry for the display such as display driver circuitry 20A in FIG. 2. Display driver integrated circuit 50 is configured to provide data and other control signals to display 14 to control operations of pixels 22.

As shown in FIG. 3A, display driver integrated circuit 50 may be mounted (attached) directly to substrate 26. Display driver integrated circuit 50 includes contacts 44 (sometimes referred to as contact pads 44, conductive contacts 44, etc.) that are configured to electrically connect to contacts 42 in substrate 26. Contacts 44 of display driver integrated circuit 50 may be bonded to contacts 42 of substrate 26 using conductive bonding structures 46 (sometimes referred to as conductive interconnect structures 46, conductive attachment structures 46, etc.). Conductive bonding structures 46 may be formed from solder, anisotropic conductive films (ACF), or another desired material. A conductive bonding structure 46 is interposed between each respective contact 42 and contact 44. Conductive bonding structures 46 are used to bond DDIC 50 to substrate 26. The conductive bonding structures may form a physical and electrical connection between DDIC 50 and substrate 26.

In addition to DDIC 50, substrate 26 may be bonded to system-in-package (SiP) 52 (sometimes referred to as integrated circuit package 52, integrated circuits package 52, electronics package 52, package 52, etc.). SiP may include a number of integrated circuits (ICs) and/or other electronic components (e.g., resistors, capacitors, inductors, etc.) enclosed in one chip carrier package. SiP 52 may include a substrate 54 upon which the one or more integrated circuits are mounted. The integrated circuits may be stacked on substrate 54, placed side by side on substrate 54, and/or embedded in substrate 54. Mold material 58 may be formed over the electronic components on the substrate to enclose the electronic components in a unitary package. Mold material 58 may conformally coat and cover the enclosed electronic components.

FIG. 3A additionally shows how conductive layer(s) 67 may be conformally applied to mold material 58. Conductive layer(s) 67 may include a single layer of conductive material or multiple layers of conductive material. Each conductive layer in conductive layer(s) 67 may comprise copper, stainless steel, nickel, iron, an alloy comprising one or more of the aforementioned materials, etc. Conductive layer(s) 67 may be conformally applied to the mold material using a physical deposition technique (e.g., sputtering, printing, spraying, etc.) or using a chemical deposition technique (e.g., plating, chemical vapor deposition, etc.). The conductive layer(s) may provide electromagnetic interference (EMI) shielding protection of electronic components in the SiP from external aggressors (i.e., radio, Wi-Fi, Bluetooth, cellular, and/or other sources). The conductive layer(s) 67 may be selectively applied to only the molded area (as indicated by the solid line in FIG. 3A) or may cover all of SiP 52 (as indicated by the additional dashed line in FIG. 3A). In other words, the conductive layer(s) 67 may optionally cover portions of substrate 54 that are not covered by mold material 58.

As shown in FIG. 3A, substrate 54 of SiP 52 may include contacts 56 (sometimes referred to as contact pads 56, conductive contacts 56, etc.). Contacts 56 are configured to electrically connect to electronic components 60, substrate 26, and flexible printed circuit 64. Substrate 54 further includes a plurality of conductive traces 54-T and a plurality of conductive vias 54-V. The conductive traces 54-T and conductive vias 54-V may route signals in a desired manner through the substrate.

A conductive bonding structure 46 is interposed between each respective contact 56 and contact 42. Conductive bonding structures 46 are used to bond substrate 54 to substrate 26. The conductive bonding structures may form a physical and electrical connection between substrate 54 and substrate 26.

Electronic components 60 may include integrated circuits (ICs), resistors, capacitors, inductors, etc. The electronic components 60 include contacts 62 (sometimes referred to as contact pads 62, conductive contacts 62, etc.) that are electrically connected to contacts 56 of substrate 54. A conductive bonding structure 46 is interposed between each respective contact 62 and contact 56. Conductive bonding structures 46 are used to bond electronic components 60 to substrate 54. The conductive bonding structures may form a physical and electrical connection between electronic components 60 and substrate 54.

Electronic components 60 may include, as one example, a timing controller (TCON) integrated circuit. The timing controller integrated circuit may provide control and/or data signals to display panel 14P. For example, the timing controller integrated circuit may receive image data and synchronize the image data with timing signals to keep the images in sync with the refresh rate of display 14.

Flexible printed circuit 64 may be formed from one or more dielectric layers formed from a flexible material such as polyimide. Metal traces may be printed on the one or more dielectric layers. Flexible printed circuit 64 includes contacts 66 (sometimes referred to as contact pads 66, conductive contacts 66, etc.) that are electrically connected to contacts 56 of substrate 54. A conductive bonding structure 46 is interposed between each respective contact 66 and contact 56. Conductive bonding structures 46 are used to bond flexible printed circuit 64 to substrate 54. The conductive bonding structures may form a physical and electrical connection between flexible printed circuit 64 and substrate 54. A first end of flexible printed circuit 64 may be bonded to substrate 54 and a second end of flexible printed circuit 64 may be bonded to a rigid printed circuit board (e.g., a main logic board) of electronic device 10.

In FIG. 3A, electronic components 60 are bonded to an upper surface of substrate 54 and substrate 26 and flexible printed circuit 64 are bonded to an opposing lower surface of substrate 54. Substrate 54 bridges a gap between substrate 26 and flexible printed circuit 64. Substrate 54 may have a first portion that overlaps flexible printed circuit 64, a second portion that overlaps a gap between flexible printed circuit 64 and substrate 26, and a third portion that overlaps substrate 26.

Display 14 may have an active area (e.g., a light-emitting area defined by the footprint of pixel array 28) and an inactive area (e.g., a non-light-emitting area around the border of the active area on display panel 14P). It may be desirable to mitigate the size of the inactive area to improve the aesthetic appearance of display 14 to a viewer. It may also be desirable for electronic device 10 to be as compact as possible.

To mitigate the size of the inactive area of display 14 and/or the size of electronic device 10, it may be desirable to mitigate the area required for bonding display panel 14P to additional electronic components. In some electronic devices, display panel 14P is bonded to a flexible printed circuit. However, the bonding area between display panel 14P and the flexible printed circuit may be greater than desired. In FIG. 3A, to mitigate the footprint of the bonding area of display panel 14P, display panel 14P is instead bonded to substrate 54 of SiP 52.

Substrate 54 of SiP 52 may be characterized as a high density (HD) substrate. The substrate has a fine pitch between adjacent conductive vias 54-V, conductive traces 54-T, etc. Consequently, the number of conductive vias 54-V per unit area and the number of conductive traces 54-T per unit area is high. This high density of conductive signal path structures allows for satisfactory performance of display 14 even with a small footprint bonding area between substrate 26 and substrate 54.

Substrate 54 may include more than 5 dielectric layers, more than 7 dielectric layers, more than 9 dielectric layers, more than 11 dielectric layers, etc. A corresponding conductive layer may be adjacent to each dielectric layer in substrate 54. The dielectric layers may be formed from polyimide, polyethylene terephthalate (PET), resin, two or more sublayers, etc. Each dielectric layer may have a thickness of less than 20 microns, less than 15 microns, less than 10 microns, less than 6 microns, etc. Each layer of conductive traces may have a thickness that is less than 20 microns, less than 15 microns, less than 10 microns, less than 6 microns, etc. Each conductive via may have a width of less than 20 microns, less than 15 microns, less than 10 microns, less than 6 microns, etc. Each contact 42 may have a maximum dimension of less than 100 microns, less than 75 microns, less than 50 microns, less than 40 microns, etc.

Mold material 58 may only cover a subset of the footprint of substrate 54. FIG. 3B is a top view of display 14. As shown in FIG. 3B, display panel 14P may have display driver circuitry 20A including DDIC 50. Substrate 54 overlaps and is mechanically and electrically connected to display panel 14P. Mold material 58 overlaps some but not all of substrate 54. As examples, mold material 58 may overlap less than 50% the total footprint of substrate 54, less than 40% the total footprint of substrate 54, less than 30% the total footprint of substrate 54, less than 20% the total footprint of substrate 54, less than 10% the total footprint of substrate 54, etc.

Substrate 54 of SiP 52 is therefore extended to additionally include portions that are not overlapped by mold material 58. The portions that are not overlapped by mold material 58 may be bonded to display panel 14P. This type of arrangement may advantageously mitigate the bonding area requirements for display panel 14P.

FIGS. 3A and 3B show examples where DDIC 50 is mounted to display panel 14P. This example is merely illustrative. If desired, DDIC 50 may be integrated into SiP 52. FIG. 4 is a cross-sectional side view of an illustrative display with a DDIC integrated into SiP 52.

As shown in FIG. 4, DDIC 50 may be mounted to substrate 54 of SiP 52. Mold material 58 may cover and conform to DDIC 50. In FIG. 4, contacts 44 of display driver integrated circuit 50 may be bonded to contacts 56 of substrate 54 using conductive bonding structures 46. A conductive bonding structure 46 is interposed between each respective contact 44 and contact 56. Conductive bonding structures 46 are used to bond DDIC 50 to substrate 54. The conductive bonding structures may form a physical and electrical connection between DDIC 50 and substrate 54. Including DDIC 50 on substrate 54 in SiP 52 may mitigate the inactive area requirements for display 14.

FIG. 4 further shows how display panel 14P may have a bent portion 14P-B that is bent around a bend axis 72. Bent portion 14P-B may not include any pixels 22 (as in FIG. 4) or may optionally include one or more pixels 22. Including bent portion 14P-B may mitigate the apparent size of the inactive area of display 14 when viewed from the front of electronic device 10. The bent portion 14P-B may better leverage the available volume of electronic device 10. Bent portion 14P-B may sometimes be referred to as a bent tail or flexible tail of the display panel.

In FIG. 4, electronic component 60 and DDIC are bonded to a lower surface of substrate 54 and substrate 26 and flexible printed circuit 64 are bonded to an opposing upper surface of substrate 54. Substrate 54 bridges a gap between substrate 26 and flexible printed circuit 64. Substrate 54 may have a first portion that overlaps flexible printed circuit 64, a second portion that overlaps a gap between flexible printed circuit 64 and substrate 26, and a third portion that overlaps substrate 26.

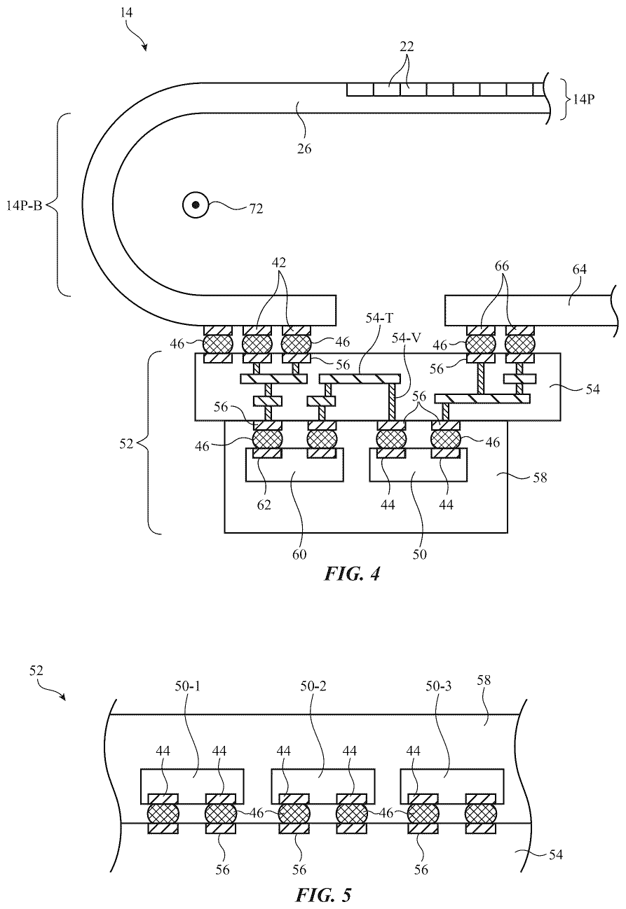

When DDIC 50 is integrated into SiP 52, the DDIC may be a single integrated circuit (as in FIG. 4) or may be split into a plurality of chiplets. FIG. 5 is a cross-sectional side view of an illustrative SiP with multiple chiplets that make up the DDIC. A first chiplet 50-1, a second chiplet 50-2, and a third chiplet 50-3 are all electrically and mechanically connected to substrate 54. As shown in FIG. 5, each chiplet has respective contacts 44 that are bonded to respective contacts 56 of substrate 54. A conductive bonding structure 46 is interposed between each respective contact 44 and contact 56. Conductive bonding structures 46 are used to bond each DDIC chiplet to substrate 54. The conductive bonding structures may form a physical and electrical connection between the chiplets and substrate 54.

Each chiplet (sometimes referred to as an integrated circuit) may include a subset of the functionality of DDIC 50. The chiplets may include both digital chiplets and analog chiplets. A digital chiplet may perform digital functions (e.g., processing, memory, input-output, etc.) whereas an analog chiplet may perform analog functions (e.g., signal processing). As an example, chiplet 50-2 may be an analog chiplet whereas chiplets 50-1 and 50-3 may be digital chiplets. Splitting the DDIC into multiple discrete chiplets as in FIG. 5 may improve design flexibility and power consumption requirements for display 14.

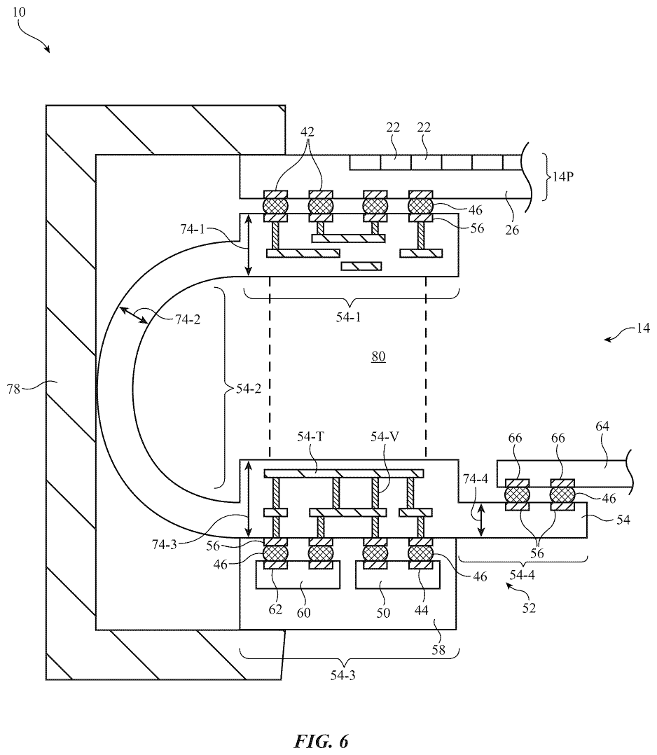

FIG. 6 shows another possible arrangement for display 14. In the example of FIG. 6, substrate 54 of SiP 52 includes multiple portions with different thicknesses. Substrate 54 has a first portion 54-1 that is bonded to display panel 14P (similar to as in FIG. 3A), a second portion 54-2 that is bent, a third portion 54-3 that is bonded to electronic components that are covered by mold material 58, and a fourth portion 54-4 that is bonded to flexible printed circuit 64. Each one of portions 54-1, 54-2, 54-3, and 54-4 may have a unique thickness. Portion 54-1 has a thickness 74-1, portion 54-2 has a thickness 74-2, portion 54-3 has a thickness 74-3, and portion 54-4 has a thickness 74-4. Thickness 74-2 may be less than thicknesses 74-1 and 74-3. The relatively small thickness of portion 54-2 may allow portion 54-2 to be easily bent. The relatively large thickness of portions 54-1 and 54-3, meanwhile, make portions 54-1 and 54-3 more robust for bonding, respectively, to substrate 26 and electronic components 50/60. Thickness 74-1 may be equal to or different than thickness 74-3. Thickness 74-2 may be equal to or different than thickness 74-4.

FIG. 6 shows how one or more additional components 80 may be interposed between portions 54-1 and 54-3 of substrate 54. In one example where electronic device 10 is a head-mounted device, the additional components 80 may include optical components such as waveguides, lenses, input couplers, etc. Instead or in addition, the additional components 80 may include a structural component that directly contacts and maintains a minimum gap between portions 54-1 and 54-3 of substrate 54. The structural component may comprise a piece of silicon or another desired material.

FIG. 6 further shows a housing structure 78. Housing structure 78 may comprise glass, plastic, metal, or any other desired material. Housing structure 78 may be an internal housing structure (e.g., an internal component that houses display 14 but is obfuscated from view by an additional housing structure) or an external housing structure that defines one or more external surfaces of electronic device 10. Housing structure 78 may sometimes be referred to as chassis 78. As shown in FIG. 6, a first portion of housing structure 78 may be attached to an upper surface of display panel 14P and a second portion of housing structure 78 may be attached to mold material 58 of SiP 52. Portion 54-2 of substrate 54 may also optionally be attached to housing structure 78.

In the example of FIG. 6, substrate 54 has a portion 54-1 that is thicker than bent portion 54-2 and that is bonded to display panel 14P. This example is merely illustrative. In another possible arrangement, bent portion 54-2 may be bonded directly to display panel 14P. In other words, the portion of substrate 54 that is bonded to display panel 14P may have the same thickness as the bent portion of substrate 54.

In yet another possible arrangement, portions 54-1 and 54-2 of substrate 54 in FIG. 6 may be replaced by a flexible printed circuit that is bonded to substrate 54 of SiP 52 and display panel 14P.

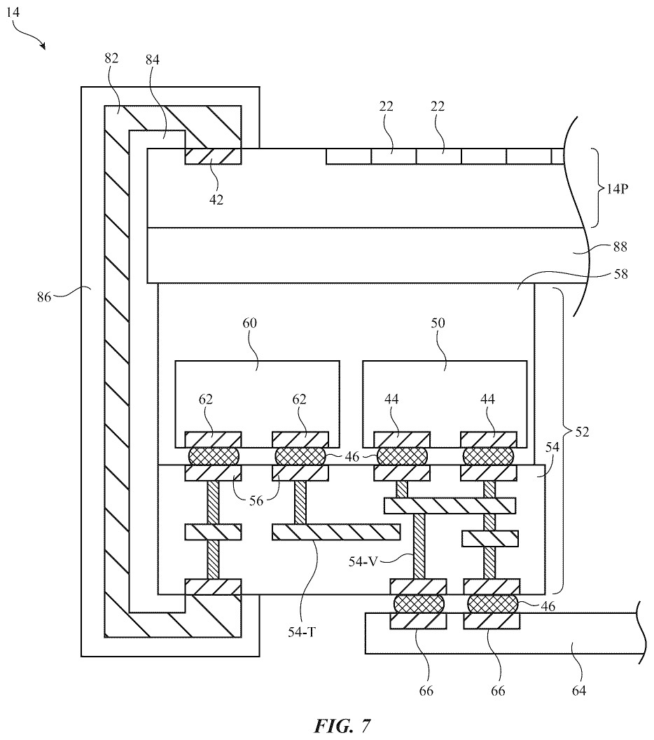

FIG. 7 is a cross-sectional side view of an illustrative display with side-wrapped conductive traces. Side-wrapped conductive traces 82 may be used to obviate the need for a bent component within display 14 (e.g., display panel 14P in FIG. 4, substrate 54 in FIG. 6, etc.) while positioning SiP 52 directly under display panel 14P.

A first insulating layer 84 may be interposed between conductive traces 82 and an edge of display panel 14P. A second insulating layer 86 may cover conductive traces 82 such that the conductive traces are interposed between the first and second insulating layers 84 and 86. Conductive traces 82 may conform to the edge of display panel 14P and SiP 52 and therefore may be referred to as being conformally wrapped around the edge of the display panel and the SiP. FIG. 7 additionally shows how an additional substrate layer 88 may be interposed between display panel 14P and SiP 52. Substrate 88 may be formed from PET or another desired material. Conductive traces 82 may conform to the edge of substrate 88 and therefore may be referred to as being conformally wrapped around the edge of substrate 88. First insulating layer 84 may conform to the edge of display panel 14P, substrate 88, and SiP 52 (e.g., substrate 54 and mold material 58). Conductive traces 82 may conform to first insulating layer 84. Second insulating layer 86 may conform to conductive traces 82. Conductive traces 82 and insulating layer 86 may also be referred to as conforming to the edge of display panel 14P, substrate 88, and SiP 52 (e.g., substrate 54 and mold material 58). There is no air gap between conductive traces 82 and the edge of display panel 14P.

There are many advantages to the arrangement of FIG. 7. The side-wrapped conductive traces occupy a minimal volume within the electronic device (where space is at a premium). The side-wrapped conductive traces allow for a narrow border to the display. The side-wrapped conductive traces may be easily formed on multiple edges of the display panel, improving IR drop and corresponding power delivery. The side-wrapped conductive traces may be robust during the manufacturing process and during drop events in real-time use.

To deposit traces 82, a very precise deposition of conductive material may be required. For example, traces 82 may be deposited (e.g., printed) on contacts 42, contacts 56, and insulating layer 84 with micron-level resolution. The traces may be printed with widths that are less than 2 microns, less than 1 micron, etc. The traces may be separated by gaps that are less than 5 microns, less than 3 microns, etc. The traces may be printed on curved surfaces (e.g., surfaces with convex curvature, compound curvature, etc.), stepped surfaces, etc. while maintaining satisfactory electrical continuity.

Additional details regarding side-wrapped conductive traces are described in U.S. application Ser. No. 18/185,237, filed Mar. 16, 2023, which is hereby incorporated by reference in its entirety.

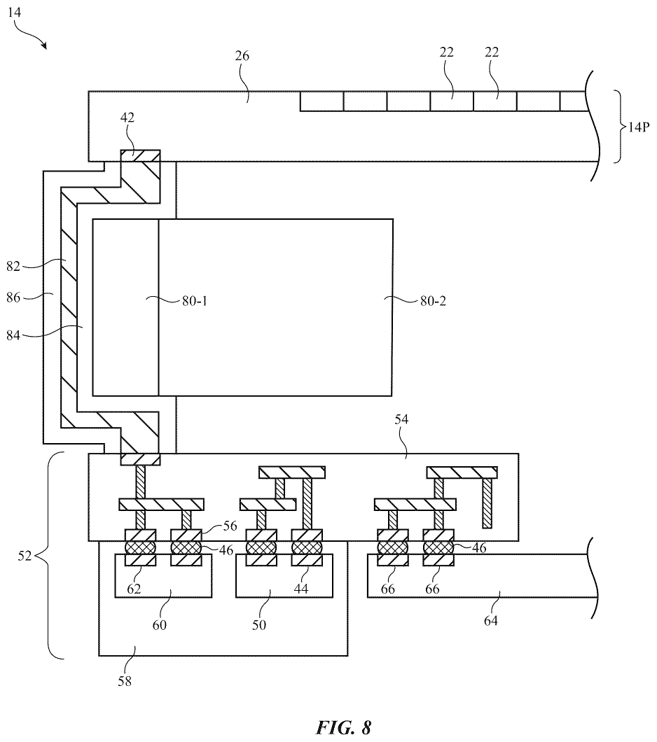

Another display with side-wrapped conductive traces is shown in FIG. 8. In the example of FIG. 8, side-wrapped conductive traces are electrically connected between contacts 42 on substrate 26 and contacts 56 on substrate 54 of SiP 52. The side-wrapped conductive traces conform to the edge of additional components 80 that are interposed between display panel 14P and SiP 52. In this example, additional components 80 include a silicon structure 80-1 and optical components 80-2. The optical components 80-2 may include waveguides, lenses, input couplers, etc. Side-wrapped conductive traces 82 conform to silicon structure 80-1. FIG. 8 depicts traces 82 that conform to the upper, lower, and edge surfaces of silicon structure 80-1. The traces may optionally conform only to the edge surface of silicon structure 80-1 if desired. Insulating layer 84 may optionally be omitted between silicon structure 80-1 and conductive traces 82 if desired.

In the arrangement of FIG. 8, flexible printed circuit 64 and electronic components 50/60 are bonded to the lower surface of substrate 54. Conductive traces 82, meanwhile, are electrically connected to the upper surface of substrate 54. This example is merely illustrative and other arrangements may be used if desired.

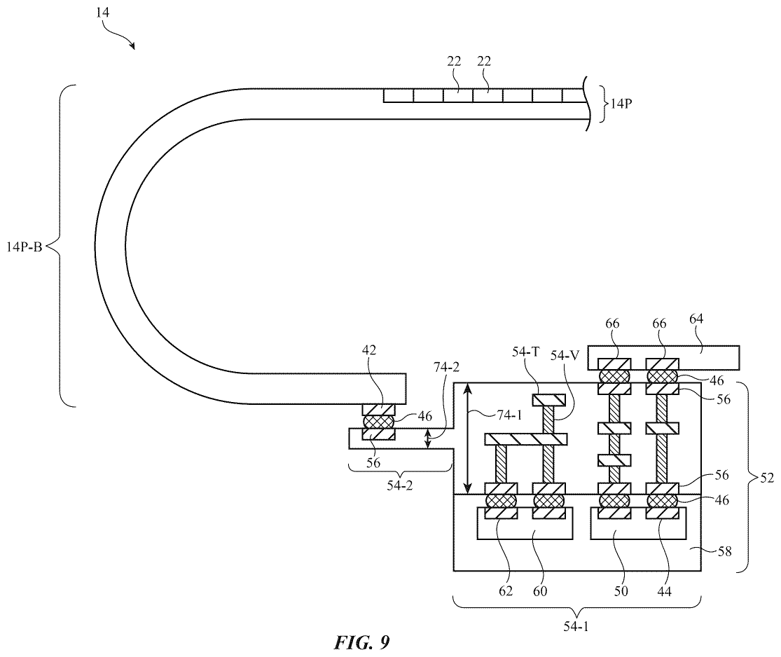

In another possible arrangement, shown in FIG. 9, display panel 14P is bonded to a protruding portion of substrate 54. As shown in FIG. 9, substrate 54 has a first portion 54-1 with a first thickness 74-1 and a second portion 54-2 with a second thickness 74-2. The second thickness 74-2 is less than thickness 74-1. Portion 54-2 protrudes from the middle of portion 54-1. Portion 54-2 has contacts 56 that are bonded to display panel 14P. In the arrangement of FIG. 9, flexible printed circuit 64 and electronic components 50/60 are bonded to opposing surfaces of substrate 54.

In the examples herein, conductive bonding structures 46 are used to bond various components within display 14. In some arrangements, different conductive bonding structures may be used for different bonds within the display. As an example, a first type of conductive bonding structure 46 may be used to bond SiP 52 to display panel 14P whereas a second, different type of conductive bonding structure 46 may be used to bond SiP 52 to flexible printed circuit 64. In some arrangements, the same conductive bonding structures may be used for different bonds within the display. As an example, a first type of conductive bonding structure 46 may be used both to bond SiP 52 to display panel 14P and to bond SiP 52 to flexible printed circuit 64. When a single type of conductive bonding structure 46 is used both to bond SiP 52 to display panel 14P and to bond SiP 52 to flexible printed circuit 64, the conductive bonding structure may comprise an ACF with low pressure and temperature requirements for bonding.

It is noted that in each one of FIGS. 3-9, mold material 58 may overlap less than 50% the total footprint of substrate 54, less than 40% the total footprint of substrate 54, less than 30% the total footprint of substrate 54, less than 20% the total footprint of substrate 54, less than 10% the total footprint of substrate 54, etc. Similarly, in each one of FIGS. 3-9, a portion of substrate 54 that is not overlapped by mold material 58 may be bonded to display panel 14P.

The foregoing is merely illustrative and various modifications can be made by those skilled in the art without departing from the scope and spirit of the described embodiments. The foregoing embodiments may be implemented individually or in any combination.

What is claimed is:

1. An electronic device, comprising:
a display panel comprising an array of pixels and a first plurality of conductive contacts; and
a package comprising a substrate, a second plurality of conductive contacts on the substrate, conductive traces within the substrate, electronic components mounted on the substrate, and mold material that overlaps and conforms to the electronic components, wherein the second plurality of conductive contacts is bonded to the first plurality of conductive contacts, wherein the substrate has a footprint, and wherein the mold material overlaps less than 50% of the footprint.

2. The electronic device defined in claim 1, further comprising:
a flexible printed circuit that is bonded to the substrate.

3. The electronic device defined in claim 1, wherein the electronic components comprise a timing controller integrated circuit.

4. The electronic device defined in claim 1, wherein the electronic components comprise a display driver integrated circuit.

5. The electronic device defined in claim 1, wherein the electronic components comprise a plurality of display driver integrated circuit chiplets.

6. The electronic device defined in claim 5, wherein the plurality of display driver integrated circuit chiplets comprises at least one digital chiplet and at least one analog chiplet.

7. The electronic device defined in claim 1, further comprising:
a display driver integrated circuit that is bonded to the display panel.

8. The electronic device defined in claim 1, wherein the display panel has a bent portion that includes the first plurality of conductive contacts.

9. The electronic device defined in claim 1, wherein the substrate has a first portion with a first thickness and a second portion with a second thickness and wherein the first and second thicknesses are different.

10. The electronic device defined in claim 9, wherein the second thickness is less than the first thickness and wherein the second portion of the substrate has the second plurality of conductive contacts.

11. The electronic device defined in claim 1, wherein the substrate has a first portion with a first thickness, a second portion with a second thickness, and a third portion with a third thickness, wherein the second thickness is less than the first and third thicknesses, wherein the second portion is interposed between the first and third portions, and wherein the second portion is bent.

12. The electronic device defined in claim 11, wherein the first portion of the substrate has the second plurality of conductive contacts.

13. The electronic device defined in claim 1, further comprising anisotropic conductive film layers that bond the first and second pluralities of conductive contacts.

14. An electronic device, comprising:
a display panel comprising first and second opposing surfaces connected by an edge surface, wherein the display panel comprises an array of pixels at the first surface;
a package that overlaps the display panel in a direction parallel to the edge surface of the display panel, wherein the package comprises a substrate, electronic components mounted on the substrate, and mold material that overlaps and conforms to the electronic components; and
conductive traces that extend in the direction parallel to the edge surface of the display panel, wherein the conductive traces electrically connect the display panel to the substrate.

15. The electronic device defined in claim 14, further comprising:
a silicon structure that is interposed between the display panel and the package, wherein the conductive traces conform to a surface of the silicon structure that is parallel to the edge surface of the display panel.

16. The electronic device defined in claim 15, further comprising:
one or more optical components that are interposed between the display panel and the package.

17. The electronic device defined in claim 14, wherein the mold material has a surface that is parallel to the edge surface of the display panel and wherein the conductive traces conform to the surface of the mold material.

18. The electronic device defined in claim 14, wherein the substrate has a surface that is parallel to the edge surface of the display panel and wherein the conductive traces conform to the surface of the substrate.

19. An electronic device, comprising:
a display panel comprising an array of pixels; and
a package comprising a substrate, electronic components mounted on the substrate, and mold material that overlaps and conforms to the electronic components, wherein a portion of the substrate that is not overlapped by the mold material is bonded to the display panel.

20. The electronic device defined in claim 19, wherein the electronic components comprise a display driver integrated circuit.
